(19) United States
(12) Patent Application Publication
(10) Pub. No.: US 2022/0068612 A1
(43) Pub. Date: Mar. 3, 2022

(54) WAFER SUPPORT AND EQUIPMENT FOR THIN-FILM DEPOSITION OR PRE-CLEANING USING THE SAME

(71) Applicant: SKY TECH INC., Hsinchu County (TW)

(72) Inventors: JING-CHENG LIN, Hsinchu County (TW); Yao-Syuan Cheng, Hsinchu County (TW)

(21) Appl. No.: 17/199,277

(22) Filed: Mar. 11, 2021

(30) Foreign Application Priority Data
Aug. 25, 2020 (TW) 109211085

(51) Int. Cl. H01J 37/32

(52) U.S. Cl. CPC H01J 37/32642; H01J 37/32715; H01J 37/32862

(57) ABSTRACT

The present disclosure provides an equipment for thin-film deposition or pre-cleaning which includes a chamber, a support pedestal, a fixing ring and a plurality of fixing members, wherein the support pedestal, the fixing ring and the fixing members are positioned within the chamber. The support pedestal has a supporting surface that supports a wafer, the fixing ring is connected to the support pedestal and surrounds the support pedestal and the wafer. When the fixing ring is disposed on the support pedestal, the fixing members contact the wafer, to fix the wafer on the support pedestal. The supporting surface of the support pedestal is at a height level same as or lower than the upper surface of the fixing ring is, to prevent the fixing ring from blocking an edge area of the wafer, to facilitate forming an evenly-distributed and steady plasma.

### TECHNICAL FIELD

The present disclosure relates to an equipment for thin-film deposition or pre-cleaning, which can prevent the fixing ring from sheltering and blocking an edge area of a wafer, thereby to facilitate forming an evenly-distributed and steady plasma on a surface of the wafer.

### BACKGROUND

Thin film deposition is a commonly employed technology for manufacturing semiconductors, such as chemical vapor deposition (CVD) and physical vapor deposition (PVD), those are mainly employed to form thin films on surfaces of wafers. In practical use, there may often be oxide layer or oxide on the surface of the wafer, which will affect quality of the thin film deposition. Also, if there is any oxide layer or oxide between the deposited thin film and the wafer, this may greatly increase contact resistance and then raise a risk of damaging wafers.

To solve the aforementioned issues, the industries nowadays commonly proceed a pre-clean process to the wafer before the deposition process, to remove oxide layer and oxide on surface of the wafers. Specifically, argon gas may be transferred into a reaction space and apply magnetic field to the reaction space, to generate argon plasma. Thereafter, a negative pressure is provided on a support pedestal supporting the wafer, this causes argon ions to hit the wafer, then to etch and remove oxide layer or oxide on the surface of the wafer.

However, there is an apparatus for fixing the wafer during the process, which shelters the wafer but also blocks an edge area of the wafer, this can cause some turbulence forming in the edge area and then result in a different etching rate between a central area and the edge area of the wafer. To be specific, the central area has an etching rate greater than that of the edge area on the wafer, which causes the central area to have a thickness less than that of the edge area on the wafer after the plasma-etching pre-clean process.

### SUMMARY

To solve the abovementioned problem of the uneven thickness on the etched wafer, the present disclosure provides a wafer support and equipment for thin-film deposition or pre-cleaning using the same, which can form an evenly-distributed and steady fluid on the surface of wafer during a thin-film deposition process or a pre-clean process, to prevent turbulence from occurring in the edge area of the wafer and facilitate forming a wafer with an even thickness after the deposition or pre-clean.

An object of the present disclosure is to provide an equipment for thin-film deposition or pre-cleaning, mainly comprising: a support pedestal, a fixing ring and a plurality of fixing portion. The support pedestal has a supporting surface for supporting at least one wafer, and the fixing ring is positioned to surround the support pedestal and the wafer. The fixing portion is disposed on an upper surface of the fixing ring, when the fixing ring is connected to the support pedestal, the fixing portion contacts the wafer on the support pedestal, to fix the wafer on the support pedestal. Furthermore, when the fixing ring is connected to the support pedestal, the upper surface of the fixing ring is at a height level same as or lower than the supporting surface of the support pedestal is, or the upper surface of the fixing ring is at a height level higher than the supporting surface of the support pedestal with a height difference therebetween less than 5 mm, to prevent the fixing ring from blocking plasma, and to prevent the plasma from forming turbulence on the edge area of the wafer adjacent to the fixing ring, thereby to improve a uniformity of the plasma on the surface of the wafer and to even a thickness of each area on the wafer after deposition or pre-cleaning.

An object of the present disclosure is to provide an equipment for thin-film deposition or pre-cleaning, mainly includes a support pedestal, a fixing ring and a plurality of fixing portions. The support pedestal has a supporting surface for supporting at least one wafer, and the fixing ring is positioned to surround the support pedestal and the wafer. Furthermore, the fixing ring is disposed with a plurality of through holes or cavities, which allows the plasma on surface of the wafer to move from the supporting surface of the support pedestal to the fixing ring in a lower position, then move to a position below the fixing ring through the through holes or cavities thereof, thereby facilitating to form an even and steady fluid and/or plasma on the surface of the wafer, and to improve the uniformity of the etched wafer.

An object of the present disclosure is to provide the abovementioned equipment for thin-film deposition or pre-cleaning, wherein the fixing ring is disposed with at least three positioning holes thereon, the chamber is disposed with at least three positioning pins therein. The positioning holes on the fixing ring are used to align with the positioning pins, thereby to position the fixing ring within the containing space of the chamber.

An object of the present disclosure is to provide the abovementioned equipment for thin-film deposition or pre-cleaning, wherein the support pedestal, the fixing ring and the fixing members are positioned within the containing space of the chamber and connected to the support pedestal via an elevating device, for driving the support pedestal to move related to the fixing ring and the fixing members. The elevating device can move the support pedestal between a conveying position and a reacting position. When the elevating device moves the support pedestal to the conveying position, a robotic arm can place a wafer on the support pedestal or carry out the pre-cleaned or thin-film deposited wafer on the support pedestal. Thereafter, the elevating device moves the support pedestal and the wafer to the reacting position, thereby the support pedestal and the wafer are within a containing space in center of the fixing ring, and the fixing members on the fixing ring contacts the wafer on the support pedestal, then fix the wafer on the support pedestal, to facilitate the pre-clean, etching or deposition process on the support pedestal.

To achieve the abovementioned purpose, the present disclosure also provides a wafer pre-cleaning apparatus, which includes: a chamber including a containing space; a gas-extraction device; at least one gas-extraction end fluidly connected to the gas-extraction device and the containing space of the chamber, wherein the gas-extraction device extracts a gas within the containing space via the gas-extraction end; at least one gas-inlet end fluidly connected to the containing space of the chamber, for transferring a cleaning gas in to the containing space; at least one coil adjacent to the chamber and electrically connected to an alternating-current (AC) power source, wherein the AC power source provides an AC to the coil to form a magnetic field within the containing space and transforms the cleaning gas within the containing space into a plasma; a support pedestal positioned in the containing space and including a supporting surface for supporting at least one wafer, wherein the support pedestal is electrically connected to a bias power source and forms a bias on the support pedestal, causes the plasma to hit the wafer on the support pedestal, for cleaning the wafer supported on the support pedestal; at least one fixing ring positioned above or to surround the support pedestal and the wafer, wherein the fixing ring has an upper surface at a height level same as or lower than the supporting surface of the support pedestal is; a plurality of fixing members connected to the fixing ring, wherein the fixing member contacts a surface of the wafer to fix the wafer on the support pedestal.

The present disclosure also provides another wafer pre-cleaning apparatus, which includes: a chamber including a containing space; a gas-extraction device; at least one gas-extraction end fluidly connected to the gas-extraction device connected to the containing space of the chamber, wherein the gas-extraction device extracts a gas within the containing space from the gas-extraction end; at least one gas-inlet end fluidly connected to the containing space of the chamber for transferring a cleaning gas to the containing space; at least one coil adjacent to the chamber and electrically connected to an AC power source, wherein the AC power source provides an AC to the coil to form a magnetic field within the containing space and transforms the cleaning gas within the containing space into a plasma; a support pedestal positioned in the containing space and including a supporting surface for supporting at least one wafer, wherein the support pedestal is electrically connected to a bias power source and forms a bias on the support pedestal, causes the plasma to hit the wafer on the support pedestal, for cleaning the wafer supported on the support pedestal; at least one fixing ring positioned above or to surround the support pedestal and the wafer, wherein an upper surface of the fixing ring is at a height level higher than the supporting surface of the support pedestal with a height difference therebetween less than 4 mm; and a plurality of fixing members connected to the fixing ring, wherein the fixing members contact a surface of the wafer to fix the wafer on the support pedestal.

### BRIEF DESCRIPTION OF THE DRAWINGS

The structure as well as preferred modes of use, further objects, and advantages of this present disclosure will be best understood by referring to the following detailed description of some illustrative embodiments in conjunction with the accompanying drawings, in which:

FIG. 1 is a schematic sectional view of an equipment for thin-film deposition or pre-cleaning according to one embodiment of the present disclosure.

FIG. 2 is a schematic perspective sectional view of a wafer support of the equipment for thin-film deposition or pre-cleaning, according to one embodiment of the present disclosure.

FIG. 3 is a schematic fragmentary sectional view of the wafer support according to one embodiment of the present disclosure.

FIG. 4 is a schematic fragmentary perspective sectional view of the wafer support according to one embodiment of the present disclosure.

FIG. 5 is a schematic fragmentary sectional view of the wafer support according to another embodiment of the present disclosure.

FIG. 6 is a schematic fragmentary sectional view of the wafer support according to another embodiment of the present disclosure.

FIG. 7 is a schematic top view of the wafer support according to one embodiment of the present disclosure.

FIG. 8 is a schematic top view of the wafer support according to another embodiment of the present disclosure.

FIG. 9 is a schematic sectional view of the equipment for thin-film deposition or pre-cleaning according to another embodiment of the present disclosure.

FIG. 10 is a schematic sectional view of the equipment for thin-film deposition or pre-cleaning according to another embodiment of the present disclosure.

### DETAILED DESCRIPTION OF THE PREFERRED EMBODIMENTS

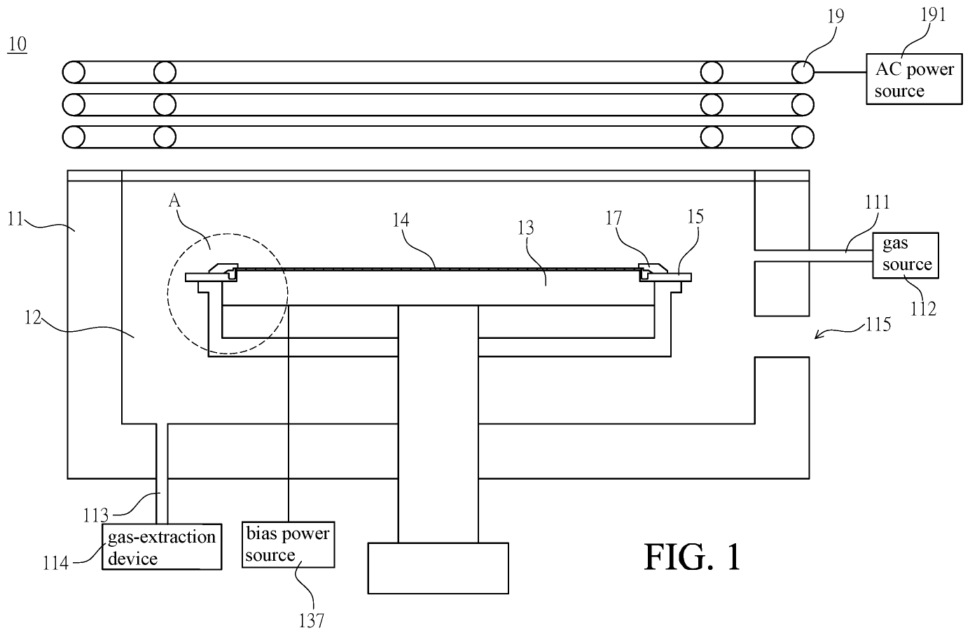

Referring to FIG. 1, which is a schematic sectional view of an equipment for thin-film deposition or pre-cleaning 10 according to one embodiment of the present disclosure. As the FIG shows, the equipment for thin-film deposition or pre-cleaning 10 mainly includes a chamber 11, and a wafer support 100. The chamber 11 has a containing space 12, the wafer support 100 is positioned within the containing space 12 the chamber 11. The wafer support 100 includes a support pedestal 13, fixing ring 15 and a fixing member 17.

The chamber 11 is disposed with at least one gas-inlet end 111 and a gas-extraction end 113, wherein the gas-inlet end 111 and the gas-extraction end 113 are fluidly connected to the containing space 12 of the chamber 11. The gas-extraction end 113 can be connected to a gas-extraction device 114, for extracting gas within the containing space 12. The gas-inlet end 111 can be connected to a gas source 112, wherein the gas source 112 may serve as a container for storing a cleaning gas or a precursor gas and transferring the cleaning gas or the precursor gas into the containing space 12 through the gas-inlet end 111. The cleaning gas or the precursor gas may be such as argon or other noble gas, and the gas-extraction device 114 may be a pump to extract the gas within the containing space 12 before, during and/or after a deposition or pre-clean process.

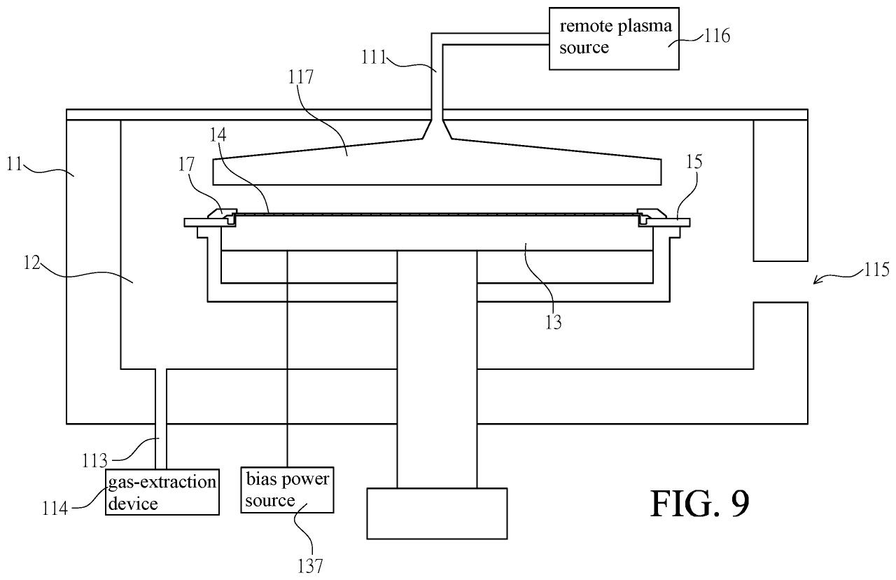

In one embodiment of the present disclosure, the containing space 12 of the chamber 11 may be disposed with a showerhead 117. As shown in FIG. 9, the showerhead 117 faces the support pedestal 113 and the wafer 14, and the gas source 112 may transfer the cleaning gas to the showerhead 117 via the gas-inlet end 111, thereby facilitating to evenly transfer the cleaning gas or precursor gas into the reaction space 12 an/or above the wafer 14.

In one embodiment of the present disclosure, the equipment for thin-film deposition or pre-cleaning 10 may include a coil 19, for pre-cleaning the wafer 14. The coil 19 is electrically connected to an alternating-current (AC) power source 191, wherein the AC power source 191 provides an AC to the coil 19 and causes the coil 19 forms a magnetic field within the containing space 12 of the chamber 11. Thereby, the cleaning gas within the containing space 12 will transform into a plasma by effect of the magnetic field, such as argon transform to argon ions. The coil 19 is positioned adjacent to the chamber 11 and also above or on a side of the chamber 11, basically just sufficient for enabling the coil 19 to generate the magnetic field within the containing space 12 of the chamber 11 then to form the plasma within the containing space 12.

The support pedestal 13 includes a supporting surface 131 for supporting at least one wafer 14. The support pedestal 13 is electrically connected to a bias power source 137, wherein the bias power source 137 is used to form a voltage on the conductive support pedestal 13. The bias power source 137 may be such as an AC power source or a direct-current (DC) power source. To be specific, when performing a pre-clean process to the wafer 14, the bias power source 137 is used to form a negative voltage on the support pedestal 13, to attract positively-charged argon ions (Ar+), and to cause the argon ions hitting and etching the wafer 14 on the support pedestal 13, thereby to remove oxide layer or oxide on a surface of the wafer 14 in order to pre-clean the wafer 14.

In the abovementioned embodiment of the present disclosure, which mainly transfers the cleaning gas to the containing space 12, then forms the magnetic field within the containing space 12 of the chamber 11 via the coil 19, thereby to transform the cleaning gas into plasma. In different embodiments, the gas source 112 may also be a remote plasma source 116, and transfer the plasma through the gas-inlet end 111 and/or the showerhead 117 into the containing space 12. As shown in FIG. 9, if the remote plasma source 116 is applied, then there is no need of disposing the coil 19 (FIG. 1) above the chamber 11.

Although, the abovementioned embodiment of the present disclosure is mainly exemplified as a pre-clean equipment, however, claim scope of the present disclosure is not limited thereto, the equipment for thin-film deposition or pre-cleaning 10 may also be an equipment for physical-vapor deposition, chemical-vapor deposition or atomic-layer deposition.

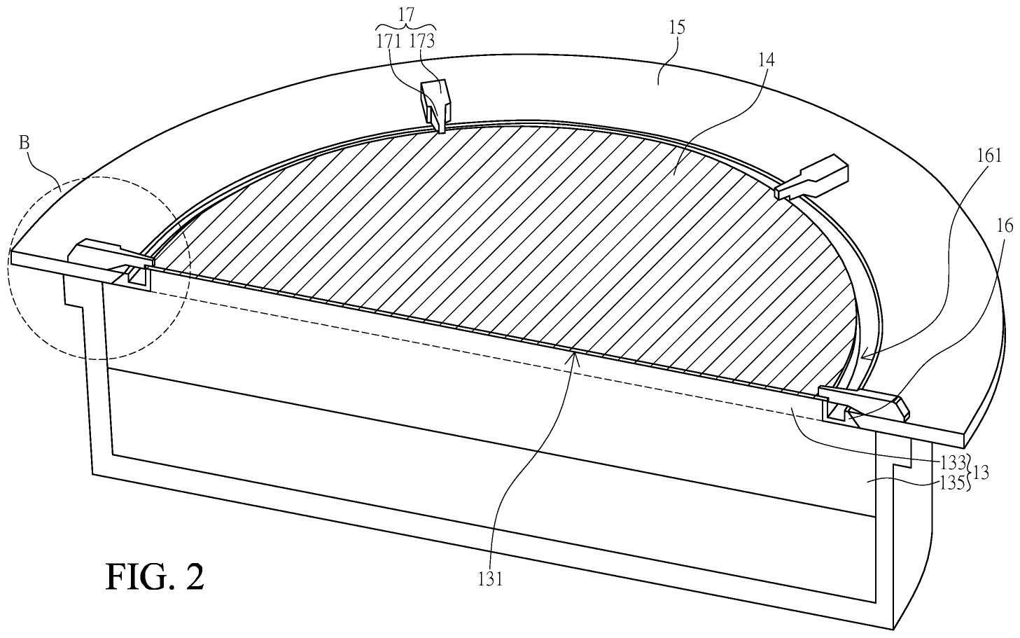

As shown in FIG. 2˜FIG. 4, the fixing ring 15 includes an upper surface 151, a lower surface 153, an outer surface 155 and an inner surface 157. The upper surface 151 and the lower surface 153 may be annular. The outer surface 155 and the inner surface 157 are side surfaces that interconnect the upper surface 151 and the lower surface 153. The outer surface 155 and the inner surface 157 are approximately round-shaped from a top view, and the outer surface 155 has a radius greater than that of the inner surface 157.

A plurality of fixing members 17 are disposed on the upper surface 151 of the fixing ring 15, wherein number of the fixing member 17 may be three or more, in order to fix the wafer 14. The fixing members 17 extend from the outer surface 155 toward the inner surface 157 of the fixing ring 15, wherein the fixing members 17 partially protrude from the inner surface 157 of the fixing ring 15. In one embodiment of the present disclosure, the fixing ring 15 has an appearance approximate to ring-shaped, and the fixing members 17 are disposed to radially extend from the fixing ring 15.

The fixing ring 15 can be connected to the support pedestal 13 then surrounds the support pedestal 13 and/or the wafer 14, wherein the fixing ring 15 and the fixing members 13 may be made of ceramic, quartz and metal. When the fixing ring 15 is disposed on the support pedestal 13, the fixing members 17 on the upper surface 151 of the fixing ring 15 contact the wafer 14 supported by the support pedestal 13, thereby to fix the wafer 14 on the support pedestal 13.

To improve a uniformity of surface etching on the wafer 14, according to the present disclosure, the upper surface 151 of the fixing ring 15 is at a height level same as or lower than the supporting surface 131 of the support pedestal 13 is, or the upper surface 151 of the fixing ring 15 is at a height level higher than the supporting surface 131 but with a height difference therebetween less than 5 millimeter (mm). The supporting surface 131 is a surface for the support pedestal 13 to support or contact the wafer 14.

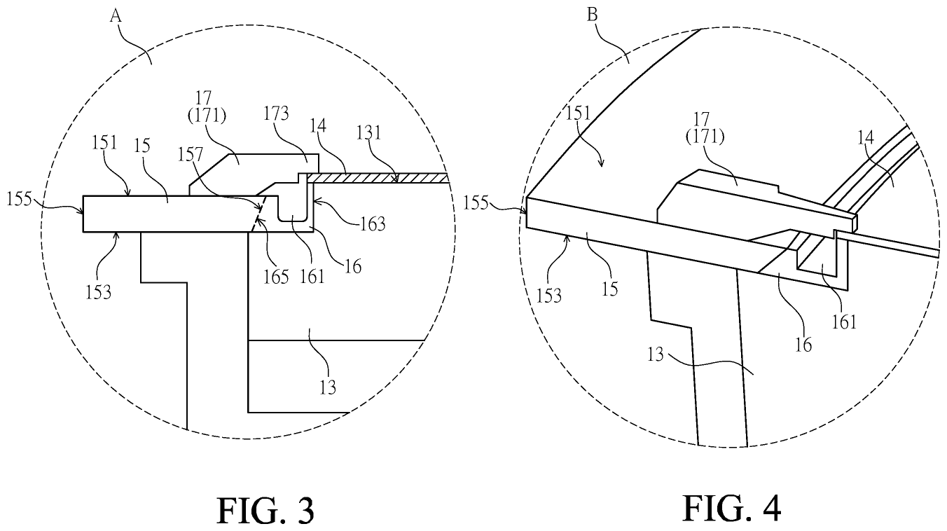

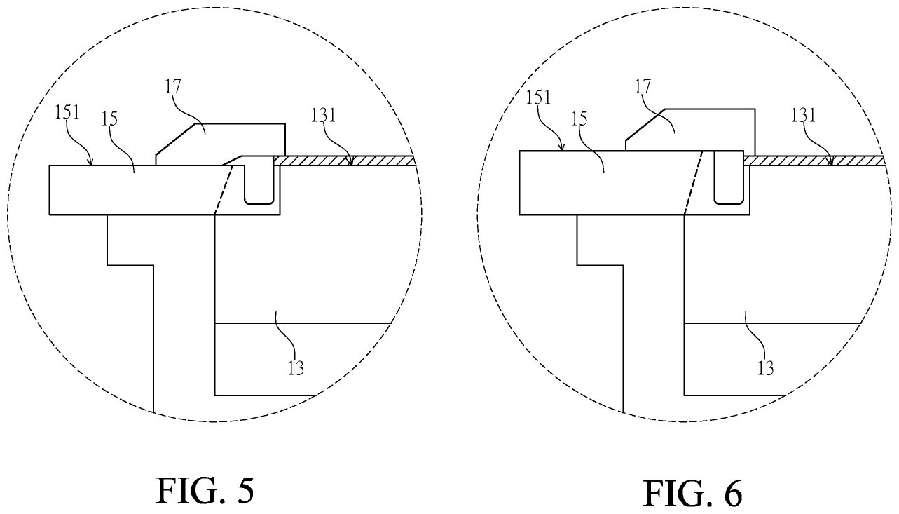

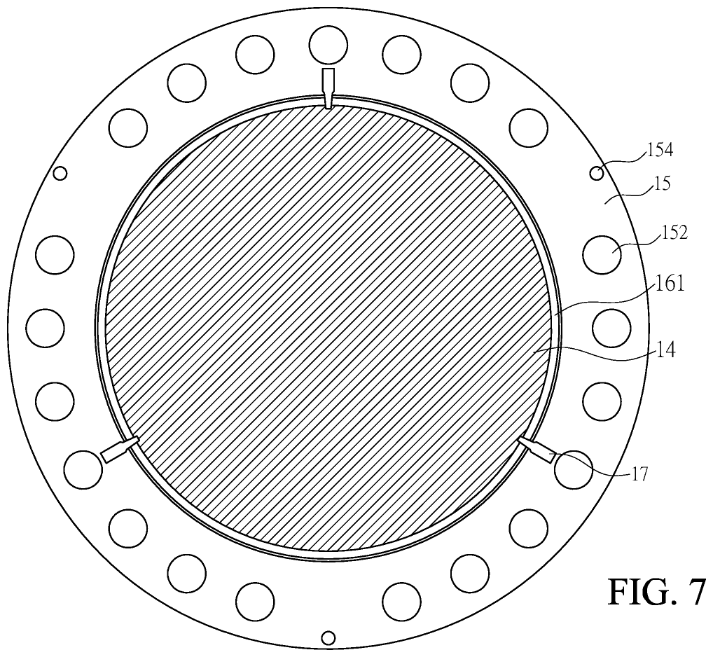

When the fixing ring 15 is connected to the support pedestal 13, the inner surface 157 of the fixing ring 15 faces the support pedestal 13, the upper surface 151 of the fixing ring 15 is substantially parallel to the supporting surface 131 of the support pedestal 13. According to the present disclosure, the upper surface 151 of the fixing ring 15 and the supporting surface 131 of the support pedestal 13 may have a spatial gap therebetween, wherein the upper surface 151 of the fixing ring 15 is at a height level same as or lower than the supporting surface 131 of the support pedestal 13 is, as shown in FIG. 3 and FIG. 4, the upper surface 151 of the fixing ring 15 is positioned lower than that of the supporting surface 131. As shown in FIG. 6, the upper surface 151 of the fixing ring 15 is at a height level higher than the supporting surface 131 of the support pedestal 13, but the height difference therebetween is less than 5 mm. Also as shown in FIG. 5, the upper surface 151 of the fixing ring 15 is substantially aligned with the supporting surface 131 of the support pedestal 13. By the disposing manner as shown in FIG. 3˜FIG. 6, all are able to prevent the fixing ring 15 from sheltering and blocking an edge area of the wafer 14, and to lessen the turbulence formed in the edge area of the wafer 14, thereby to facilitate improving the uniformity of surface etching on the wafer 14.

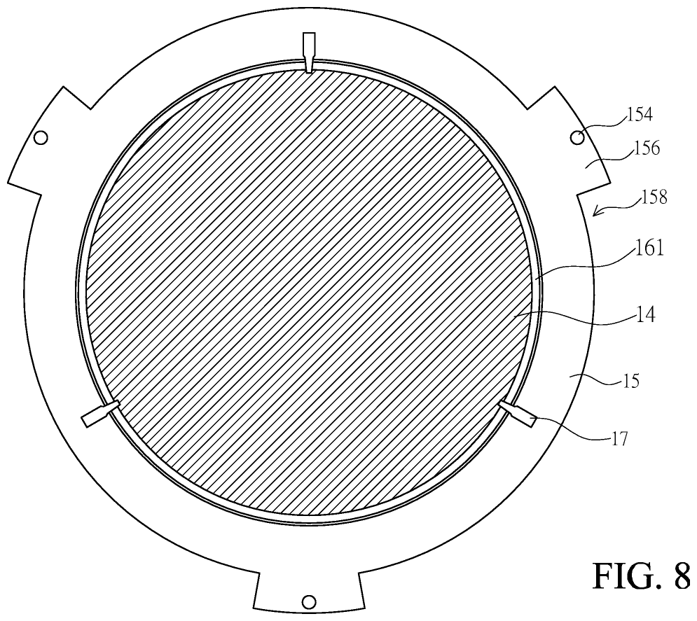

In practical use, as shown in FIG. 7 and FIG. 8, the fixing ring 15 may be disposed with at least three positioning holes 154, the chamber 11 may be disposed with at least three positioning pins (not shown). The positioning holes 154 of the fixing ring 15 can be aligned with the positioning pins of the chamber 11, and be positioned, mounted within in the containing space 12 of the chamber 11.

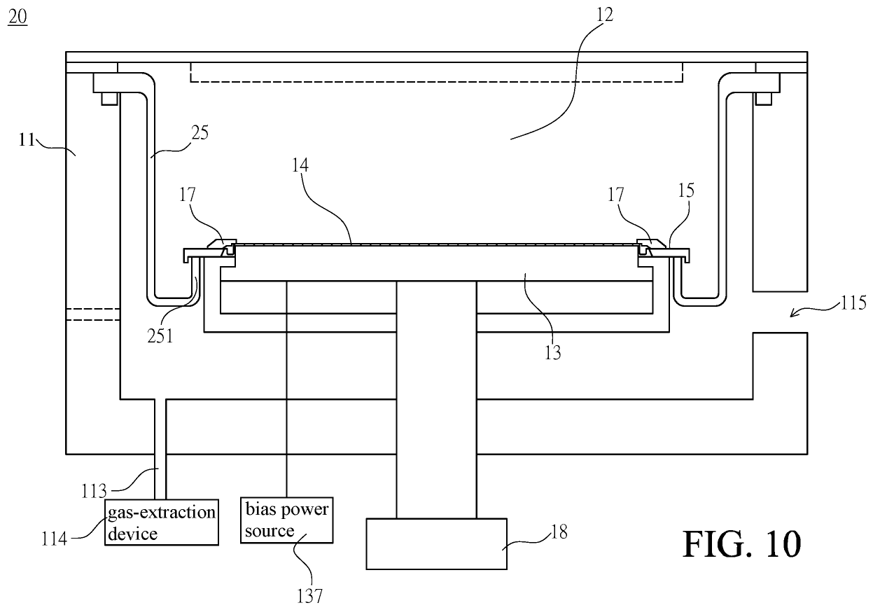

In another embodiment of the present disclosure as shown in FIG. 10, the equipment for thin-film deposition or pre-clean 20 may have a structure similar to that of the aforementioned embodiments, but mainly different in that the equipment 20 further includes a blocking member 25 disposed within the chamber 11 and an elevating device 18 for driving the support pedestal 13, and also the fixing ring 15 disposed with the fixing members 17 is separate from the support pedestal 13. To be specific, the blocking member 25 is disposed within the containing space 12 of the chamber 11, the blocking member 25 has an end connected to the chamber 11 and another formed with a hanger portion 251, wherein the hanger portion 251 is used for supporting and positioning the fixing ring 15. The elevating device 18 is connected to the support pedestal 13, for driving the support pedestal 13 and the wafer 14 to move related to the fixing ring 15, as so to allow the wafer 14 supported by the support pedestal 13 to contact the fixing members 17 on the fixing ring 15, and thereby to fix and secure the wafer 14 on the support pedestal 13.

To be specific, as shown in FIG. 1, the elevating device 18 can drive the support pedestal 13 to descend to a conveying position, then transport the wafer 14 onto the supporting surface 131 of the support pedestal 13 through a material passage by a robotic arm. Thereafter the elevating device 18 drives the support pedestal 13 and the wafer 14 to ascend, and enables the support pedestal 13 to contact and connect the fixing ring 15, then the wafer 14 on the support pedestal 13 contacts the fixing member 17 and fixes the wafer 14 on the support pedestal 13 by the fixing members 17.

As shown in FIG. 2, in one embodiment of the present disclosure, the support pedestal 13 of the wafer support 100 can be disposed with an annular structure 16 thereon. The annular structure 16 includes an annular cavity 161, the annular structure 16 and the annular cavity 161 thereof are disposed to surround the support pedestal 13. Specifically, the support pedestal 13 includes a protruding portion 133 and a bottom portion 135, wherein the protruding portion 133 is disposed on the bottom portion 135, and the bottom portion 135 has a sectional area larger than the protruding portion 133. The supporting surface 131 is a top surface of the protruding portion 133, and the annular structure 16 is mounted to surround the protruding portion 133 of the support pedestal 13, such that the annular structure 16 and the annular cavity 161 thereof are disposed to surround the protruding portion 133. In a different embodiment, the annular structure 16 may also be formed integrally with the support pedestal 13, thereby the annular structure 16 and the support pedestal 13 are one single component.

The annular structure 16 may include an inner surface 163 and an outer surface 165. When the annular structure 16 is mounted on the protruding portion 133 of the support pedestal 13, the inner surface 163 of the annular structure 16 contacts a surface of the protruding portion 133 of support pedestal 13, and the outer surface 165 of the annular structure 16 will contact the inner surface 157 of the fixing ring 15. As shown in FIG. 3 and FIG. 4, the outer surface 165 on the annular structure 16 may be an inclined plane, and the inner surface 157 of the fixing ring 15 may also be an inclined plane. The inclined plane on the inner surface 157 of the fixing ring 15 matches the inclined plane on the outer surface 165 of the annular structure 16, with approximately identical slope. When the elevating device 18 drives the support pedestal 13 to ascend and connect to the fixing ring 15, then via both of the inclined plane on the outer surface 165 and the inner surface 157, the fixing ring 15 is guided to a holding position.

In one embodiment of the present disclosure, each of the fixing members 17 may include a bottom portion 171 and a fixing portion 173. For each of the fixing member 17, the bottom portion 171 is connected to the upper surface 151 of the fixing ring 15, wherein the fixing portion 173 has an end connected to the bottom portion 171 and another end extending toward the wafer 14 and/or the support pedestal 13 and protruding from the inner surface 157 of the fixing ring 15. Also, for each of the fixing member 17, the bottom portion 171 may have a width, a thickness and/or a cross section less than that of the fixing portion 173.

Another embodiment of the present disclosure as shown in FIG. 7, the fixing ring 15 may have a plurality of through holes 152 disposed thereon, wherein each of the through holes 152 extends from the upper surface 151 to the lower surface 153 of the fixing ring 15, and all of the through holes 152 are arrayed around the wafer 14 and the support pedestal 13.

According to the present disclosure, the upper surface 151 of the fixing ring 15 is at a height level same as or lower than the supporting surface 131 of the support pedestal 13 and the wafer 14 are, or the upper surface 151 of the fixing ring 15 at a height level higher than the supporting surface 131 of the support pedestal 13 but with the height difference therebetween less than 5 mm. Thereby, the plasma is attracted by the voltage on the support pedestal 13 to hit the surface of the wafer 14, then move from the supporting surface 131 of the support pedestal 13 to the fixing ring 15, and then be transferred to a position below the fixing ring 15. Such that, an evenly-distributed and steady fluid and/or plasma can be formed on the surface of the wafer 14, to improve the result uniformity for etching the wafer, and to prevent the problem of the uneven thickness between the edge area and the central area of the wafer in the conventional technology.

In another embodiment of the present disclosure, as shown in FIG. 8, the fixing ring 15 may also have a plurality of convex portions 156 and concave portions 158 disposed on an edge thereon. The convex portions 156 protrude radially outward from the fixing ring 15, and the positioning holes 154 are disposed on the convex portions 156. The convex portions 156 and the concave portions 158 are disposed adjacent to each other and around the wafer 14 and the support pedestal 13. In practical use, the concave portions 158 disposed on the fixing ring 15 can serve a function similar to the through holes 152.

The above disclosure is only the preferred embodiment of the present disclosure, and not used for limiting the scope of the present disclosure. All equivalent variations and modifications on the basis of shapes, structures, features and spirits described in claims of the present disclosure should be included in the claims of the present disclosure.

We claim:

1. An equipment for thin-film deposition or pre-cleaning, comprising:
a chamber comprising a containing space;
a gas-extraction device;
at least one gas-extraction end fluidly connected to the gas-extraction device and the containing space of the chamber;
at least one gas-inlet end fluidly connected to the containing space of the chamber for transferring a gas to the containing space;
a support pedestal positioned within the containing space, wherein the support pedestal comprises a supporting surface for supporting at least one wafer, the support pedestal is electrically connected to a bias power source to form a bias on the support pedestal;
at least one fixing ring positioned above the support pedestal or positioned to surround the support pedestal and the wafer, wherein the at least one fixing ring has an upper surface that is at a height level same as or lower than the supporting surface of the support pedestal is; and
a plurality of fixing members connected to the upper surface of the at least one fixing ring, wherein the fixing members contact a surface of the wafer and fix the wafer on the support pedestal.

2. The equipment for thin-film deposition or pre-cleaning as claimed in claim 1, further comprising an annular structure disposed on the support pedestal, wherein the annular structure comprises at least one annular cavity, the annular structure and the at least one annular cavity thereof are disposed to surround the support pedestal, and the at least one fixing ring is disposed to surround the annular structure.

3. The equipment for thin-film deposition or pre-cleaning as claimed in claim 2, wherein:
the annular structure has an inner surface connected to the support pedestal, and an outer surface disposed with an inclined plane;
the at least one fixing ring has an inner surface disposed with an inclined plane that matches the inclined plane of the outer surface of the annular structure;
the support pedestal includes a protruding portion;
the supporting surface is a top surface of the protruding portion;
the annular structure is mounted to surround the protruding portion of the support pedestal; and the annular cavity of the annular structure is disposed to surround the protruding portion of the support pedestal.

4. The equipment for thin-film deposition or pre-cleaning as claimed in claim 1, further comprising:
a blocking member disposed within the containing space of the chamber, having an end that is connected to the chamber and another end that is formed with a hanger portion, wherein the hanger portion is used for supporting and positioning the at least one fixing ring; and
an elevating device connected to the support pedestal for driving the support pedestal and the wafer to move related to the at least one fixing ring, thereby to allow the wafer supported by the support pedestal to contact the fixing members on the at least one fixing ring and to fix the wafer on the support pedestal.

5. The equipment for thin-film deposition or pre-cleaning as claimed in claim 1, wherein:
each of the fixing members includes a bottom portion and a fixing portion; and
for each of the fixing members, the bottom portion is disposed on the upper surface of the at least one fixing ring, and the fixing portion is connected to the bottom portion and extends toward the wafer.

6. The equipment for thin-film deposition or pre-cleaning as claimed in claim 1, further comprising a showerhead disposed within the containing space of the chamber, wherein the least one gas-inlet end is fluidly connected to the showerhead and transfers the gas into the containing space through the showerhead.

7. The equipment for thin-film deposition or pre-cleaning as claimed in claim 1, further comprising at least one coil adjacent to the chamber and electrically connected to an alternating-current (AC) power source, wherein, the AC power source provides an AC to the coil, to form a magnetic field within the containing space, thereby to transform the gas within the containing space into a plasma by effect of the magnetic field, and the plasma is attracted by the bias on the support pedestal to hit the wafer on the support pedestal for cleaning the wafer.

8. The equipment for thin-film deposition or pre-cleaning as claimed in claim 1, wherein the at least one fixing ring comprises at least three positioning holes and be positioned relative to the chamber via the positioning holes.

9. The equipment for thin-film deposition or pre-cleaning as claimed in claim 1, wherein the at least one fixing ring further comprises a plurality of through holes or a plurality of concave portions disposed around the support pedestal.

10. An equipment for thin-film deposition or pre-cleaning, comprising:
a chamber comprising a containing space;
a gas-extraction device;
at least one gas-extraction end fluidly connected to the gas-extraction device and the containing space of the chamber;
at least one gas-inlet end fluidly connected to the containing space of the chamber for transferring a gas to the containing space;
a support pedestal positioned within the containing space, wherein the support pedestal comprises a supporting surface for supporting at least one wafer, the support pedestal is electrically connected to a bias power source to form a bias on the support pedestal;
at least one fixing ring positioned above the support pedestal or positioned to surround the support pedestal and the wafer, wherein the at least one fixing ring has an upper surface at a height level higher than the supporting surface of the support pedestal, with a height difference between the upper surface of the at least one fixing ring and the supporting surface of the support pedestal less than 4 millimeter (mm); and
a plurality of fixing members connected to the upper surface of the at least one fixing ring, wherein the fixing members contacts a surface of the wafer and fix the wafer on the support pedestal.

11. The equipment for thin-film deposition or pre-cleaning as claimed in claim 10, further comprising:
a blocking member disposed within the containing space of the chamber, having an end that is connected to the chamber and another end that is formed with a hanger portion, wherein the hanger portion is used for supporting and positioning the at least one fixing ring; and
an elevating device connected to the support pedestal for driving the support pedestal and the wafer to move related to the at least one fixing ring, thereby to allow the wafer supported by the support pedestal to contact the fixing members on the at least one fixing ring and to fix the wafer on the support pedestal.

12. The equipment for thin-film deposition or pre-cleaning as claimed in claim 10, further comprising a showerhead disposed within the containing space of the chamber, wherein the least one gas-inlet end is fluidly connected to the showerhead and transfers the cleaning gas into the containing space through the showerhead.

13. The equipment for thin-film deposition or pre-cleaning as claimed in claim 10, further comprising at least one coil adjacent to the chamber and electrically connected to an alternating-current (AC) power source, wherein the AC power source provides an AC to the coil, to form a magnetic field within the containing space, thereby to transform the gas within the containing space into a plasma by effect of the magnetic field, and the plasma is attracted by the bias on the support pedestal to hit the wafer on the support pedestal for cleaning the wafer.

14. The equipment for thin-film deposition or pre-cleaning as claimed in claim 10, wherein:
the at least one fixing ring comprises at least three positioning holes and be positioned relative to the chamber via the positioning holes;
the at least one fixing ring comprises a plurality of through holes or a plurality of concave portions; and
the through holes or the concave portions are disposed around the support pedestal.

15. A wafer support, comprising:
a support pedestal comprising a supporting surface for supporting at least one wafer, wherein the support pedestal is electrically connected to a bias power source to form a bias on the support pedestal;
at least one fixing ring positioned above the support pedestal or positioned to surround the support pedestal and the wafer, wherein the at least one fixing ring has an upper surface that is at a height level same as or lower than the supporting surface of the support pedestal is; and
a plurality of fixing members connected to the upper surface of the at least one fixing ring, wherein the fixing members contacts a surface of the wafer and fix the wafer on the support pedestal.

16. The wafer support as claimed in claim 15, further comprising an annular structure disposed on the support pedestal, wherein the annular structure comprises at least one annular cavity, the annular structure and the at least one annular cavity thereof are disposed to surround the support pedestal, and the at least one fixing ring is disposed to surround the annular structure.

17. The wafer support as claimed in claim 16, wherein:
the annular structure has an inner surface connected to the support pedestal, and an outer surface disposed with an inclined plane; and
the at least one fixing ring has an inner surface disposed with an inclined plane that matches the inclined plane of the outer surface of the annular structure.

18. The wafer support as claimed in claim 15, wherein:
each of the fixing members includes a bottom portion and a fixing portion;
the bottom portion is disposed on the upper surface of the at least one fixing ring; and
the fixing portion is connected to the bottom portion and extends toward the wafer.

19. The wafer support as claimed in claim 15, wherein the at least one fixing ring comprises at least three positioning holes.

20. The wafer support as claimed in claim 15, wherein:
the at least one fixing ring comprises a plurality of through holes or a plurality of concave portions; and
the through holes or the concave portions are disposed around the support pedestal.
